(19) United States
(12) Patent Application Publication
(10) Pub. No.: US 2026/0310178 A1
(43) Pub. Date: Oct. 8, 2026

(54) CONSTRUCTION MANAGEMENT DEVICE AND CONSTRUCTION MANAGEMENT METHOD

(71) Applicant: JGC CORPORATION, Yokohama-shi, Kanagawa (JP)

(72) Inventor: Daichi HATANAKA, Yokohama-shi (JP)

(73) Assignee: JGC CORPORATION, Yokohama-shi, Kanagawa (JP)

(21) Appl. No.: 18/874,878

(22) PCT Filed: Jul. 8, 2022
(86) PCT No.: PCT/JP2022/027085

§ 371 Date: Dec. 13, 2024

(51) Int. Cl. G05B 19/418

(52) U.S. Cl. CPC G05B 19/4183; G05B 19/4184

(57) ABSTRACT

Provided is a construction management device including: a storage unit configured to store: design document information on a facility; and facility information in which the facility and instruments connected to lines provided to the facility are associated with each other; and an inspection document creation unit configured to identify some of the instruments that are connected to one of the lines based on the facility information, and extract and integrate pieces of information relating to the one of the lines and the some of the instruments from the design document information to create inspection documents required for an inspection of the one of the lines.

### TECHNICAL FIELD

The present disclosure relates to a construction management device and a construction management method.

### BACKGROUND ART

In construction of an instrumentation system for a large-scale plant or the like, an inspection (hereinafter also referred to as “loop check”) to examine whether or not instruments (such as pressure gauges and flow meters) connected to a line (loop) provided to the instrumentation system are correctly wired and whether or not signals such as control signals are correctly communicated between the instruments is carried out. For example, in an instrumentation system for a large-scale plant, the number of lines that require loop checks may exceed tens of thousands of loops. In this case, a huge amount of work is required to create inspection documents required for loop checks.

The system drawing checking device as described in Patent Literature 1 is capable of creating a system drawing that is electronic data. Further, in the system drawing checking device as described in Patent Literature 1, facility information is acquired for each facility included in a tracing section designated by a user in the system drawing, and lines in the tracing section are checked.

### CITATION LIST

### Patent Literature

PTL 1: JP 2019-174946 A

### SUMMARY OF INVENTION

### Technical Problem

However, related-art construction management devices as described in Patent Literature 1 and the like do not have a function of providing support in creation of inspection documents required for loop checks on lines (loops) or a function of systematically managing loop checks. Therefore, a huge amount of time and effort still have been required for users to perform work for creating inspection documents and managing loop checks.

The present disclosure has been made in view of the above-mentioned circumstances, and has an object to provide a construction management device and a construction management method that provide support in work regarding loop checks on lines (loops).

### Solution to Problem

In order to solve the above-mentioned problem, the present disclosure proposes the following means.

According to a first aspect of the present disclosure, there is provided a construction management device including: a storage unit configured to store: design document information on a facility; and facility information in which the facility and instruments connected to lines provided to the facility are associated with each other; and an inspection document creation unit configured to identify some of the instruments that are connected to one of the lines based on the facility information, and extract and integrate pieces of information relating to the one of the lines and the some of the instruments from the design document information to create inspection documents required for an inspection of the one of the lines.

According to a second aspect of the present disclosure, there is provided a construction management method including: identifying, based on facility information in which a facility and instruments connected to lines provided to the facility are associated with each other, some of the instruments that are connected to one of the lines; and extracting and integrating pieces of information relating to the one of the lines and the some of the instruments from design document information on the facility to create inspection documents required for an inspection of the one of the lines.

### Advantageous Effects of Invention

According to the construction management device and the construction management method of the present disclosure, it is possible to provide support in work regarding loop checks on the lines (loops).

### BRIEF DESCRIPTION OF DRAWINGS

FIG. 1 A configuration diagram of a construction management system according to one embodiment.

FIG. 2 A functional block diagram of a construction management device of the construction management system.

FIG. 3 A table for showing plant information.

FIG. 4 A table for showing inspection document definition information.

FIG. 5 A table for showing inspection dependency relationship information.

FIG. 6 A table for showing inspection information.

FIG. 7 A functional block diagram of an inspection management unit of the construction management device.

FIG. 8 A diagram for illustrating an example of a method of generating inspection documents.

FIG. 9 A table for showing an example of a determination result of feasibility of a loop check.

FIG. 10 A diagram for illustrating an example of a generated inspection format.

FIG. 11 A view for illustrating an application for inputting results of the loop check.

### DESCRIPTION OF EMBODIMENTS

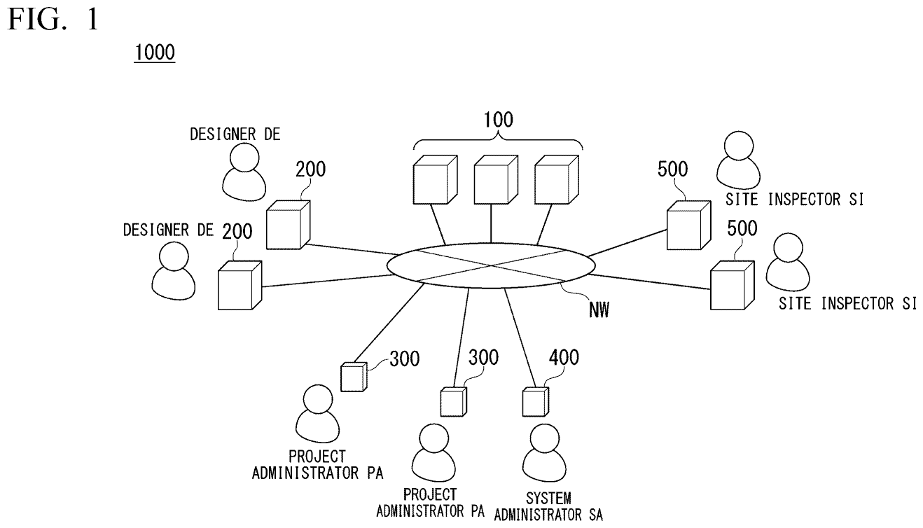

One embodiment of the present disclosure is described with reference to FIG. 1 to FIG. 11. FIG. 1 is a configuration diagram of a construction management system 1000 according to this embodiment.

### Construction Management System 1000

The construction management system 1000 is a system that manages construction of a large-scale plant. The construction management system 1000 includes a construction management device 100, a design document management device 200, a terminal 300, a management terminal 400, and a site management device 500. The construction management device 100, the design document management device 200, the terminal 300, the management terminal 400, and the site management device 500 are connected to each other through a network NW, and may be installed in different countries or different regions.

The network NW may be a wide area network (WAN) such as what is called the Internet, may be a private network (LAN) in a building in which the construction management system 1000 is installed, or may be a combination of those. The network NW may also be of any one of wired communication or wireless communication. Another device such as an access point may be interposed in communication between devices.

The construction management device 100 is a management device including one or more servers, which manages the construction of the large-scale plant. The servers are each a computer including a processor such as a CPU, a memory, a recording medium such as a hard disk or a flash memory, and a communication device. When the construction management device 100 is formed of a plurality of servers, the plurality of servers may be servers having different types of OSs, software, and the like. The plurality of servers may also be operated by different operating entities. The plurality of servers may be installed in different countries or different regions. The plurality of servers may be a system that combines an on-site server and a cloud server that provides an infrastructure as a service (IaaS), a platform as a service (PaaS), or software as a service (Saas). In the following description, the “server” includes any one of the above-mentioned servers.

The design document management device 200 is a server that manages design documents regarding designs and inspections of facility modules of the large-scale plant. The design document management device 200 is, for example, a server to which design documents regarding designs and inspections created by a designer DE of the large-scale plant are uploaded. The construction management device 100 may have at least some of functions of the design document management device 200.

The terminal 300 is a terminal such as a smartphone, a tablet terminal, or a personal computer owned by a project administrator PA involved in the construction of the large-scale plant. The project administrator PA carries out management and the like of a project involved in the construction of the large-scale plant through the terminal 300. The project administrator PA may directly operate the construction management device 100 without intermediation of the terminal 300.

The management terminal 400 is a terminal owned by a system administrator SA of the construction management device 100. The system administrator SA carries out management and the like of the construction management device 100 through the management terminal 400. The system administrator SA may directly operate the construction management device 100 without intermediation of the management terminal 400.

The site management device 500 is a server installed on a site on which the large-scale plant is constructed, which manages processes of the construction of the plant (including work relating thereto). The site management device 500 is operated by a site inspector SI. The construction management device 100 may have at least some of functions of the site management device 500.

### Construction Management Device 100

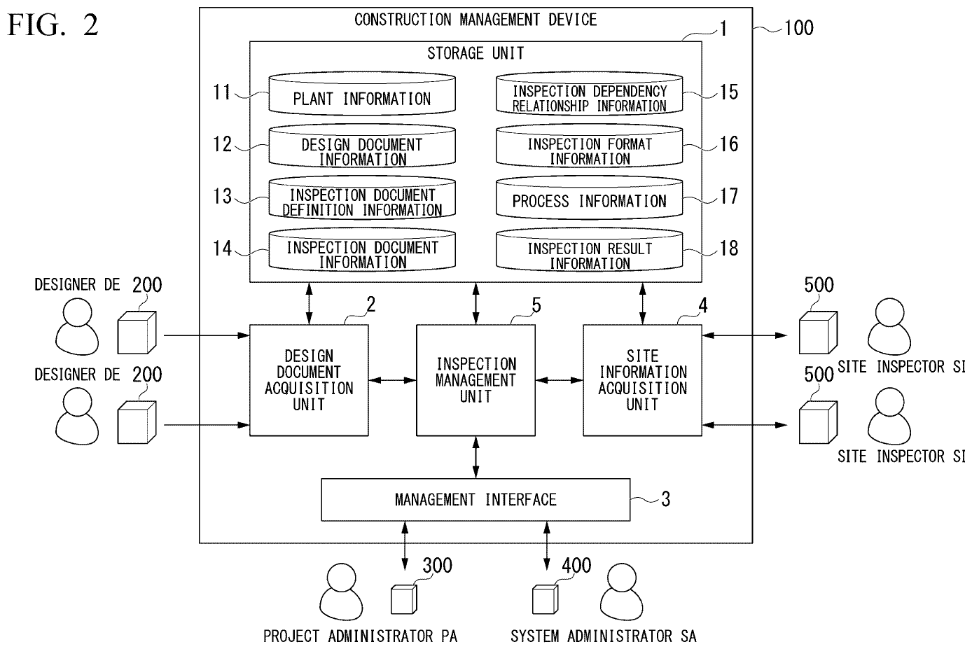

FIG. 2 is a functional block diagram of the construction management device 100.

The construction management device 100 includes a storage unit 1, a design document acquisition unit 2, a management interface 3, a site information acquisition unit 4, and an inspection management unit 5.

Functions of the functional blocks (storage unit 1, design document acquisition unit 2, management interface 3, site information acquisition unit 4, and inspection management unit 5) of the construction management device 100 are implemented by the processor executing a construction management program provided to the construction management device 100. The construction management device 100 may include a logic circuit that executes at least some of arithmetic operations and the like of the construction management device 100.

### Storage Unit 1

The storage unit 1 is a non-volatile recording medium that stores the construction management program that operates the construction management device 100 and data required for construction management, and is, for example, a storage device such as a hard disk drive (HDD) or a solid state drive (SSD). The storage unit 1 stores plant information 11, design document information 12, inspection document definition information 13, inspection document information 14, inspection dependency relationship information 15, inspection format information 16, process information 17, and inspection result information 18.

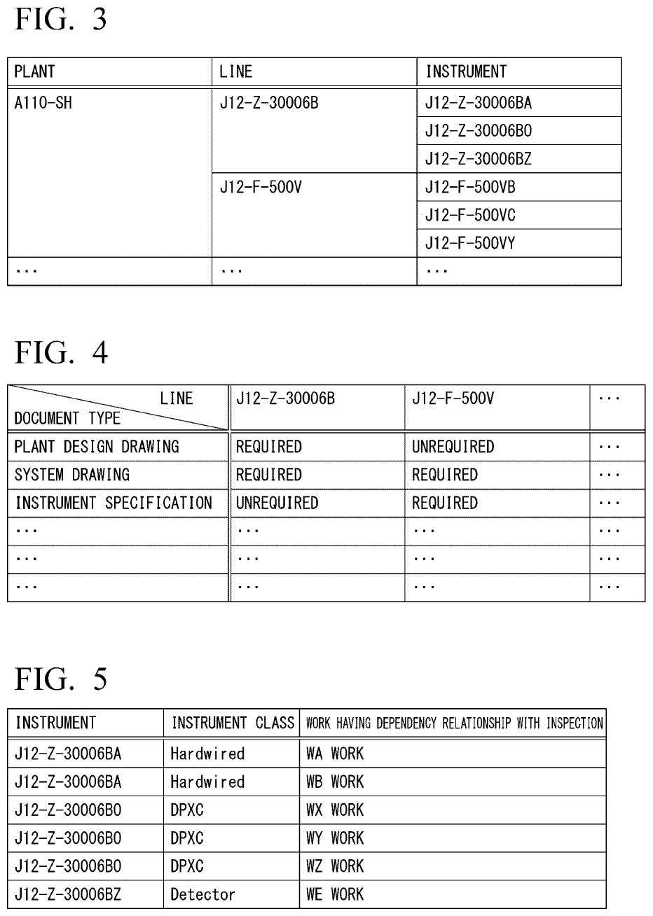

FIG. 3 is a table for showing the plant information 11.

The plant information (facility information) 11 is information relating to a plant. As shown in FIG. 3, the plant information 11 is information in which the plant (facility), a line (hereinafter also referred to as “loop”) provided to an instrumentation system for the plant, and an instrument (such as a gauge or a valve) connected to the line are associated with each other. A plant type, a line type, and an instrument type are represented by “tags” formed of alphanumeric symbols. The tags are unique in the construction management system 1000 and have no overlap.

The design document information 12 is information relating to the design documents of the plant. The design document information 12 includes a design drawing of the plant, a system drawing (document) of the instrumentation system for the plant, and a specification (document) of an instrument connected to the line (loop). The design document information 12 is stored in association with the tags.

FIG. 4 is a table for showing the inspection document definition information 13.

The inspection document definition information 13 is information that defines inspection documents (hereinafter also referred to as “loop package”) required for an inspection (hereinafter also referred to as “loop check”) to examine whether or not instruments connected to a line (loop) provided to the instrumentation system for the plant are correctly wired and whether or not signals such as control signals are correctly communicated between the instruments. As shown in FIG. 4, the inspection document definition information 13 is information that defines, for each line, the types of the design documents included in the inspection documents required for the loop check.

The inspection document information 14 is information relating to documents required for the loop check. The inspection document information 14 includes the inspection documents (loop package) created by extracting from the design document information 12 based on the inspection document definition information 13. The inspection document information 14 is stored in association with the tags.

FIG. 5 is a table for showing the inspection dependency relationship information 15.

The inspection dependency relationship information 15 is information that defines, for each instrument, work (construction, inspection, in-service delivery, and the like) having dependency relationships with the loop check. For example, as shown in FIG. 5, an instrument “J12-Z-30006BA” is classified into a function class “Hardwired,” and in order to inspect the instrument “J12-Z-30006BA,” work WA and work WB that have dependency relationships therewith are required to have been completed. In addition, an instrument “J12-Z-30006BO” is classified into a function class “DPXC,” and in order to inspect the instrument “J12-Z-30006BO,” work WX, work WY, and work WZ that have dependency relationships therewith are required to have been completed. The work having a dependency relationship is defined for each instrument function class.

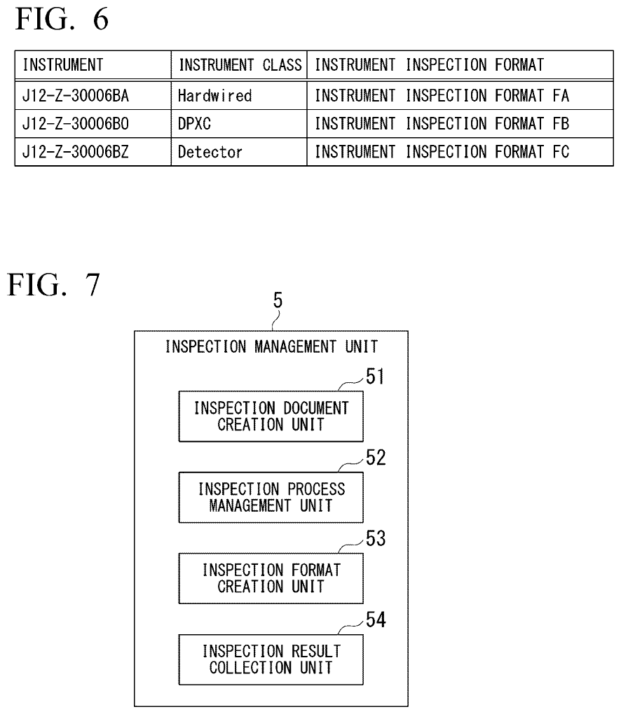

FIG. 6 is a table for showing the inspection format information 16.

The inspection format information 16 is information that defines, for each instrument, an inspection format (inspection items, test records, and the like) (also referred to as “ITR”) to be used when a loop check is carried out. For example, as shown in FIG. 6, an instrument “J12-Z-30006BA” is classified into the function class “Hardwired” and is required to be loop-checked based on an inspection format FA. In addition, an instrument “J12-Z-30006 BO” is classified into the function class “DPXC” and is required to be loop-checked based on an inspection format FB. The inspection format is defined for each instrument function class. The inspection format includes, for example, inspection items and inspection pass criteria for the inspection items.

The process information 17 is information regarding the processes of the construction of the plant. The process information 17 includes the processes of the construction of the plant (including work relating thereto). The process information 17 is stored in association with the tags.

The inspection result information 18 is information regarding results of inspections of the plant. The inspection result information 18 includes the results of the loop check. The inspection result information 18 is stored in association with the tags.

### Design Document Acquisition Unit 2

The design document acquisition unit 2 is connected to the design document management device 200 through an interface including an application programming interface (API), and acquires the design documents created by the designer DE from the design document management device 200 (design document acquisition step). The design document acquisition unit 2 records the acquired design documents in the storage unit 1 as the inspection document information 14.

The design document acquisition unit 2 may, for example, periodically acquire the design documents collectively from the design document management device 200 to update the inspection document information 14 recorded in the storage unit 1. The design document acquisition unit 2 may also acquire the design documents individually from the design document management device 200 as the requirement arises.

The designer DE may directly upload the created design documents to the design document acquisition unit 2 of the construction management device 100. In this case, the design document acquisition unit 2 records the received design documents in the storage unit 1 as the inspection document information 14.

### Management Interface 3

The management interface 3 is an interface connected to the terminal 300 and the management terminal 400. Specifically, the management interface 3 includes an API that connects the terminal 300 and the management terminal 400 to the inspection management unit 5.

The project administrator PA can access the inspection management unit 5 through the management interface 3 through use of an application running on the terminal 300. The project administrator PA accesses the inspection management unit 5 to, for example, create inspection documents (loop package).

The system administrator SA can access the inspection management unit 5 through the management interface 3 through use of an application running on the management terminal 400. The system administrator SA accesses the inspection management unit 5 to, for example, set up connections between the construction management device 100, the design document management device 200, and the site management device 500.

The applications running on the terminal 300 and the management terminal 400 may be web applications or native applications.

### Site Information Acquisition Unit 4

The site information acquisition unit 4 is connected to the site management device 500 through an interface including an API, acquires information relating to the site from the site management device 500, and records the information in the storage unit 1. Specifically, the site information acquisition unit 4 acquires the processes of the construction of the plant (including work relating thereto) from the site management device 500, and records the processes in the storage unit 1 as the process information 17 (construction process acquisition step). The site information acquisition unit 4 also acquires the results of the loop check from the site management device 500, and records the results in the storage unit 1 as the inspection result information 18 (inspection result acquisition step).

The site information acquisition unit 4 may, for example, periodically acquire pieces of information relating to the site collectively from the site management device 500 to update the process information 17 and the inspection result information 18 that are recorded in the storage unit 1. The site information acquisition unit 4 may also acquire the pieces of information relating to the site individually from the site management device 500 as the requirement arises.

The site inspector SI may directly upload the information relating to the site (processes of the construction of the plant and results of the loop check) to the site information acquisition unit 4 of the construction management device 100. In this case, the site information acquisition unit 4 records the received information relating to the site in the storage unit 1 as the process information 17 and the inspection result information 18.

### Inspection Management Unit 5

FIG. 7 is a functional block diagram of the inspection management unit 5.

The inspection management unit 5 manages inspections for the construction of the large-scale plant. The inspection management unit 5 includes an inspection document creation unit 51, an inspection process management unit 52, an inspection format creation unit 53, and an inspection result collection unit 54.

The inspection document creation unit 51 creates inspection documents (loop package) based on the plant information 11, the design document information 12, and the inspection document definition information 13. The inspection document creation unit 51 creates, based on the tag of a line of the plant designated by the project administrator PA, inspection documents regarding the relevant line.

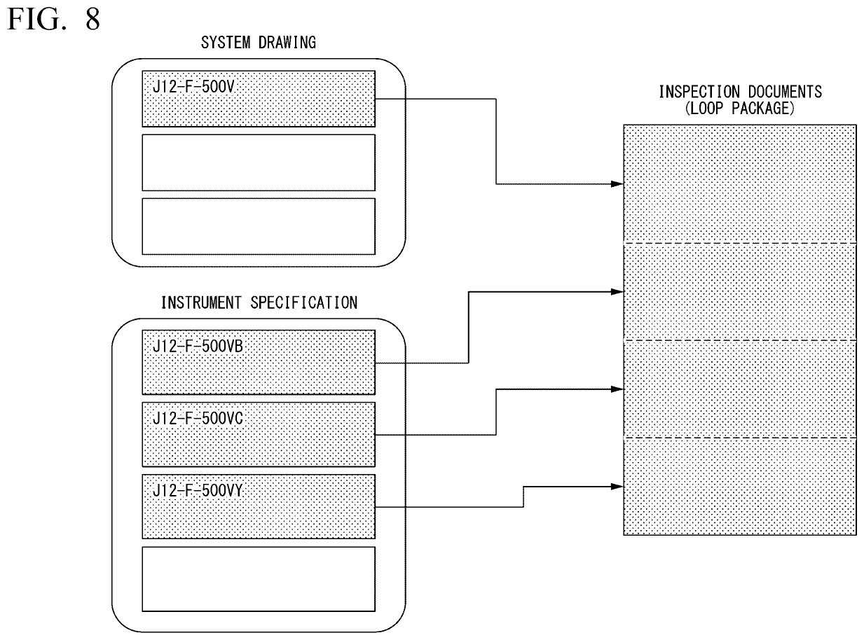

FIG. 8 is a diagram for illustrating an example of a method of generating inspection documents.

A method for the inspection document creation unit 51 to create inspection documents regarding a line “J12-F-500V” of a plant “A110-SH” shown in FIG. 3 is described below. The project administrator PA uses the application running on the terminal 300 to input an instruction to cause the inspection document creation unit 51 to create inspection documents regarding the line “J12-F-500V.” The inspection document creation unit 51 identifies the instruments connected to the line “J12-F-500V” from the plant information 11 shown in FIG. 3 to acquire the tags (J12-F-500VB, J12-F-500VC, and J12-F-500VY) of the instruments. Subsequently, the inspection document creation unit 51 acquires types (system drawing and instrument specification) of the design documents included in the inspection documents required for the loop check of the line “J12-F-500V” from the inspection document definition information 13 of FIG. 4. Subsequently, as illustrated in FIG. 8, the inspection document creation unit 51 generates inspection documents by extracting and integrating all the design documents given the tags of the instruments among the design documents included in the inspection documents required for the loop check, or some pages of the design documents that are distinguished by the tags of the instruments.

The inspection document creation unit 51 regenerates the inspection documents through use of the most recent design documents when the design document recorded in the storage unit 1 as the design document information 12 and included in the inspection documents required for the loop check is updated.

The project administrator PA can automatically generate inspection documents required for the loop check of the relevant line simply by designating the tag of the line. The project administrator PA can also easily regenerate the inspection documents when the design document forming the inspection documents is updated.

In the example of generating inspection documents which is illustrated in FIG. 8, the number of instruments connected to the line is small, and the number of types of design documents required for the loop check is small. However, in actual generation of inspection documents, the number of instruments connected to the line is large, and the number of types of design documents required for the loop check is also large. Therefore, the generation and regeneration of inspection documents by the inspection document creation unit 51 is more efficient than manual creation of inspection documents by the user. In addition, the generation and regeneration of inspection documents by the inspection document creation unit 51 is error-free and accurate.

The inspection process management unit 52 preliminarily determines feasibility of a loop check on the relevant line (loop) based on the plant information 11, the inspection dependency relationship information 15, and the process information 17. In this case, the preliminary determination is information that is provided to the project administrator PA by the inspection process management unit 52, and is used by the project administrator PA to determine the feasibility of the loop check.

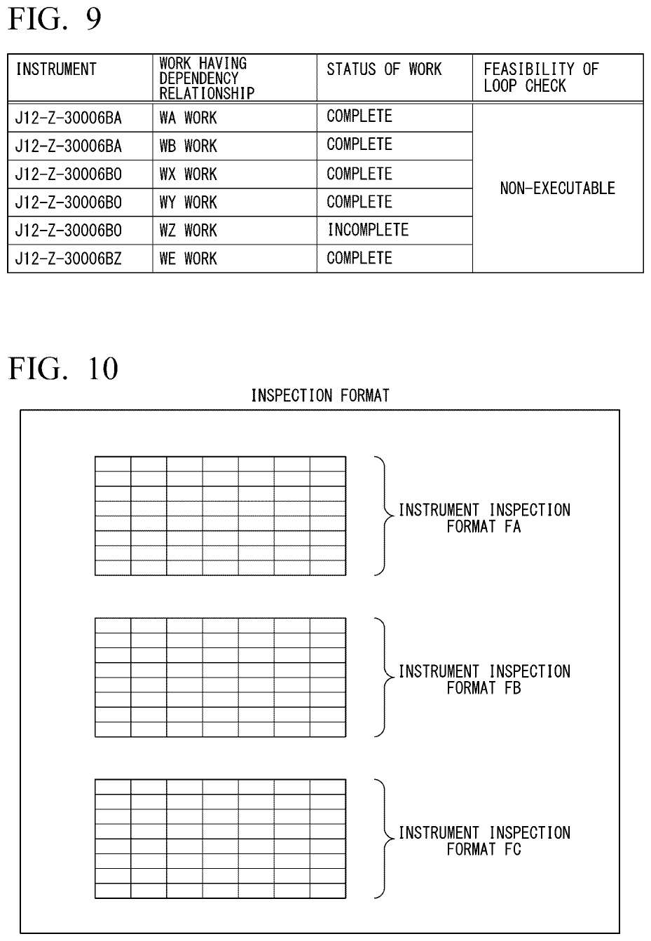

FIG. 9 is a table for showing an example of a preliminary determination result of the feasibility of the loop check.

A method for the inspection process management unit 52 to preliminarily determine the feasibility of the loop check regarding a line “J12-Z-30006B” of the plant “A110-SH” shown in FIG. 3 is described below. The project administrator PA uses the application running on the terminal 300 to input an instruction to cause the inspection process management unit 52 to preliminarily determine the feasibility of the loop check regarding the line “J12-Z-30006B”. The inspection process management unit 52 identifies the instruments connected to the line “J12-Z-30006B” from the plant information 11 shown in FIG. 3 to acquire the tags (J12-Z-30006BA, J12-Z-30006BO, and J12-Z-30006BZ) of the instruments. Subsequently, the inspection process management unit 52 identifies pieces of work (work WA, work WB, work WX, work WY, work WZ, and work WO) having dependency relationships with the inspections of the connected instruments from the inspection dependency relationship information 15 shown in FIG. 5. Subsequently, the inspection process management unit 52 examines statuses of the pieces of work having the dependency relationships from the process information 17. When all the statuses of the pieces of work having the dependency relationships are “COMPLETE,” the inspection process management unit 52 preliminarily determines that the loop check regarding the line “J12-Z-30006B” is “EXECUTABLE.” When at least one of the statuses of the pieces of work having the dependency relationships is “INCOMPLETE,” the inspection process management unit 52 preliminarily determines that the loop check regarding the line “J12-Z-30006B” is “NON-EXECUTABLE.” The inspection process management unit 52 transmits the preliminary determination result to the terminal 300. The terminal 300 displays such a preliminary determination result of the feasibility of the loop check as shown in FIG. 9 on a display screen of the terminal 300.

The project administrator PA can preliminarily determine the feasibility of the loop check on the relevant line simply by designating the tag of the line. When the preliminary determination result is “NON-EXECUTABLE,” the project administrator PA can identify the incomplete piece of work that is preventing the loop check from being carried out.

The inspection format creation unit 53 generates, based on the plant information 11 and the inspection format information 16, an inspection format F (inspection items, test records, and the like) to be used when the loop check is carried out on the relevant line (loop).

FIG. 10 is a diagram for illustrating an example of the generated inspection format F.

A method for the inspection format creation unit 53 to generate the inspection format F for the line “J12-Z-30006B” of the plant “A110-SH” shown in FIG. 3 is described below. The project administrator PA uses the application running on the terminal 300 to input an instruction to cause the inspection format creation unit 53 to generate the inspection format F for the line “J12-Z-30006B.” The inspection format creation unit 53 identifies the instruments connected to the line “J12-Z-30006B” from the plant information 11 shown in FIG. 3 to acquire the tags (J12-Z-30006BA, J12-Z-30006BO, and J12-Z-30006BZ) of the instruments. Subsequently, the inspection format creation unit 53 acquires instrument inspection formats (instrument inspection format FA, instrument inspection format FB, and instrument inspection format FC) for the respective connected instruments from the inspection format information 16 shown in FIG. 6. The inspection format creation unit 53 integrates the instrument inspection formats for the respective instruments to generate such an inspection format F for the line “J12-F-500V” as illustrated in FIG. 10.

The project administrator PA can generate the inspection format F (inspection items, test records, and the like) to be used when the loop check is carried out on the relevant line (loop) simply by designating the tag of the line.

The inspection result collection unit 54 causes the results of the loop check to be input from the site management device 500 based on the inspection format F created by the inspection format creation unit 53, and aggregates the results of the loop check.

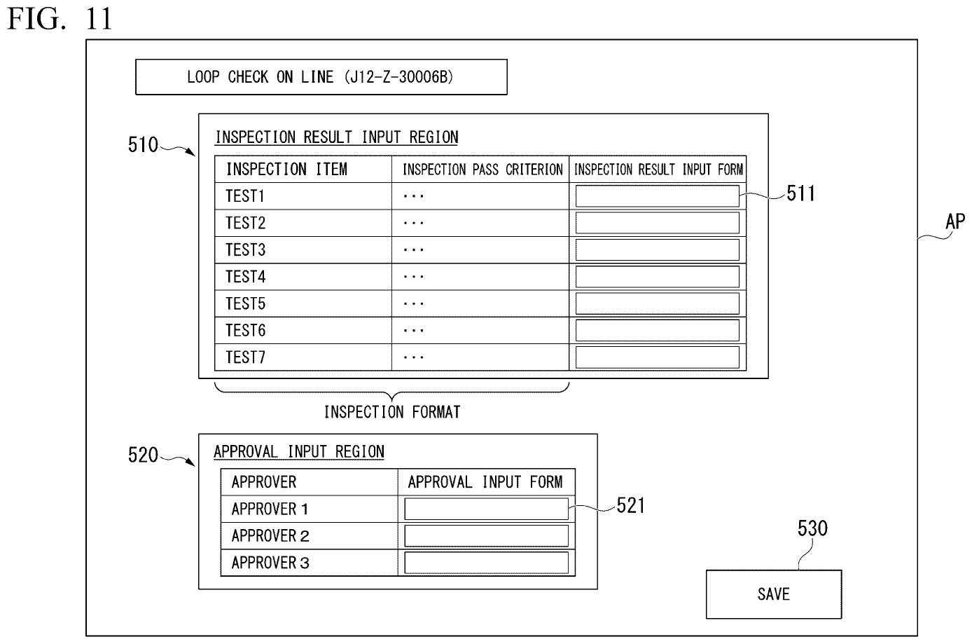

FIG. 11 is a view for illustrating an application AP for inputting the results of the loop check.

A method for the inspection result collection unit 54 to collect the results of the loop check for the line “J12-Z-30006B” of the plant “A110-SH” shown in FIG. 3 is described below. The inspection result collection unit 54 is connected to the site management device 500 through the site information acquisition unit 4, and transmits the inspection format F for the line “J12-F-500V” to the site management device 500. The application AP running on the site management device 500 generates an “inspection result input region 510” regarding the loop check for the line “J12-F-500V” based on the received inspection format F, and presents the inspection result input region 510 to the site inspector SI. The application AP may be a web application or a native application.

The inspection result input region 510 includes, for example, an inspection item and an inspection pass criterion, which are included in the inspection format F, and an inspection result input form 511 for the inspection item. The site inspector SI can input an inspection result for each inspection item in the inspection result input form 511.

The application AP may include an “approval input region 520” as illustrated in FIG. 11. The approval input region 520 includes, for example, an approver and an approval input form 521. A plurality of approvers included in the site inspectors SI can input approval for the inspection results in the approval input form 521.

After the input of the inspection results (and approval) to the application AP, the site inspector SI operates a save button 530 to save the input data. The inspection result collection unit 54 acquires the input data from the application AP. The inspection result collection unit 54 stores the acquired input data in the storage unit 1 as the inspection result information 18.

The project administrator PA can electronically and centrally manage the inspection formats F to be used for loop checks for lines (loops) and the results of inspections based on the inspection formats F.

With the construction management device 100 according to this embodiment, the project administrator PA can centrally manage the work regarding loop checks for lines (loops), and can support the project administrator PA in work regarding the loop checks. Specifically, the project administrator PA can automatically generate and regenerate inspection documents (loop package) required for the loop check of a relevant line simply by designating the tag of the line. The project administrator PA can determine the feasibility of the loop check on the relevant line simply by designating the tag of the line. The project administrator PA can generate the inspection format F to be used when the loop check is carried out on the relevant line simply by designating the tag of the line. The project administrator PA can electronically and centrally manage the inspection formats F to be used for loop checks for lines and the results of inspections based on the inspection formats F.

The above-mentioned functions may be implemented by recording a program in each embodiment in a computer-readable recording medium and causing a computer system to read and execute the program stored in this recording medium. The “computer system” includes an OS and hardware such as peripheral devices. Further, the “computer-readable recording medium” refers to a portable medium such as a flexible disk, a magneto-optical disk, a ROM, and a CD-ROM or a storage device such as a hard disk drive built in the computer system. Further, the “computer-readable recording medium” may include an entity for dynamically holding a program for a short period of time such as a communication wire through which the program is transmitted via a network such as the Internet or a communication line such as a phone line, and also include an entity for holding a program for a certain period of time such as a volatile memory inside the computer system serving as a server or a client in that case. Further, the program may implement some of the above-mentioned functions, or may implement the above-mentioned functions in combination with programs already recorded in the computer system.

### Industrial Applicability

The construction management device and the construction management method according to the present disclosure are applicable to a device, a system, and the like that manage inspections of lines provided with a large number of instruments.

### REFERENCE SIGNS LIST

1000 construction management system
100 construction management device
1 storage unit
11 plant information (facility information)
12 design document information
13 inspection document definition information
14 inspection document information
15 inspection dependency relationship information
16 inspection format information
17 process information
18 inspection result information
2 design document acquisition unit
3 management interface
4 site information acquisition unit
5 inspection management unit
51 inspection document creation unit
52 inspection process management unit
53 inspection format creation unit
54 inspection result collection unit

1. A construction management device, comprising:
a storage unit configured to store: design document information on a facility; and facility information in which the facility and instruments connected to lines provided to the facility are associated with each other; and
an inspection document creation unit configured to identify some of the instruments that are connected to one of the lines based on the facility information, and extract and integrate pieces of information relating to the one of the lines and the some of the instruments from the design document information to create inspection documents required for an inspection of the one of the lines.

2. The construction management device according to claim 1,
wherein the storage unit is configured to record inspection document definition information that defines, for each of the lines, types of the design document information included in the inspection documents, and
wherein the inspection document creation unit is configured to extract, from the design document information, the pieces of information relating to the one of the lines and the some of the instruments based on the inspection document definition information.

3. The construction management device according to claim 2,
wherein the facility information has the lines and the instruments identified by tags having no overlap,
wherein the design document information and the inspection document definition information are stored in association with the tags, and
wherein the inspection document creation unit is configured to identify the some of the instruments that are connected to the one of the lines based on the tags, and extract the pieces of information relating to the one of the lines and the some of the instruments based on the tags.

4. The construction management device according to claim 1,
wherein the storage unit is configured to store process information regarding processes of construction of the facility, and
wherein the construction management device further comprises an inspection process management unit configured to provide information for determining feasibility of the inspection on the one of the lines based on the facility information and the process information.

5. The construction management device according to claim 4,
wherein the storage unit is configured to record inspection dependency relationship information that defines, for each of the instruments, pieces of work having dependency relationships with the inspection of each of the lines, and
wherein the inspection process management unit is configured to:
identify, based on the inspection dependency relationship information, some of the pieces of work having dependency relationships with the inspection the feasibility of which is to be determined; and
examine some of the processes regarding the identified some of the pieces of work from the process information to provide the information for determining the feasibility.

6. The construction management device according to claim 1,
wherein the storage unit is configured to record inspection format information that defines, for each of the instruments, an instrument inspection format to be used at a time of the inspection of the each of the instruments, and
wherein the construction management device further comprises an inspection format creation unit configured to acquire the instrument inspection formats for the some of the instruments that are connected to the one of the lines from the inspection format information, to create an inspection format to be used at a time of the inspection of the one of the lines.

7. The construction management device according to claim 6, further comprising an inspection result collection unit configured to collect inputs of results of the inspection of the one of the lines, which have been input based on the inspection format, and record the inputs of the results in the storage unit.

8. The construction management device according to claim 7, wherein the inspection result collection unit is configured to collect inputs of approval performed by approvers, together with the inputs of the results of the inspection of the one of the lines, and record the inputs of the approval in the storage unit.

9. A construction management method, comprising:
identifying, based on facility information in which a facility and instruments connected to lines provided to the facility are associated with each other, some of the instruments that are connected to one of the lines; and
extracting and integrating pieces of information relating to the one of the lines and the some of the instruments from design document information on the facility to create inspection documents required for an inspection of the one of the lines.

10. The construction management method according to claim 9, further comprising integrating the pieces of information relating to the one of the lines and the some of the instruments to create the inspection documents based on inspection document definition information that defines, for each of the lines, types of the design document information included in the inspection documents.

11. The construction management method according to claim 10,
wherein the facility information has the lines and the instruments identified by tags having no overlap,
wherein the design document information and the inspection document definition information are associated with the tags,
wherein the some of the instruments that are connected to the one of the lines are identified based on the tags, and
wherein the pieces of information relating to the one of the lines and the some of the instruments are extracted from the design document information based on the tags.

12. The construction management method according to claim 9, further comprising providing information for determining feasibility of the inspection on the one of the lines based on process information regarding processes of construction of the facility and the facility information.

13. The construction management method according to claim 12, further comprising:
identifying, based on inspection dependency relationship information that defines, for each of the instruments, pieces of work having dependency relationships with the inspection of each of the lines, some of the pieces of work having dependency relationships with the inspection the feasibility of which is to be determined; and
examining some of the processes regarding the identified some of the pieces of work from the process information to provide the information for determining the feasibility.

14. The construction management method according to claim 9, further comprising:
acquiring, from inspection format information that defines, for each of the instruments, an instrument inspection format to be used at a time of the inspection of the each of the instruments, the instrument inspection formats for the some of the instruments that are connected to the one of the lines from the inspection format information; and
creating an inspection format to be used at a time of the inspection of the one of the lines.

15. The construction management method according to claim 14, further comprising collecting inputs of results of the inspection of the one of the lines, which have been input based on the inspection format.

16. The construction management method according to claim 15, further comprising collecting inputs of approval performed by approvers, together with the inputs of the results of the inspection of the one of the lines.
